(19) United States
(12) Patent Application Publication
(10) Pub. No.: US 2003/0217813 A1
(43) Pub. Date: Nov. 27, 2003

(54) Plasma processing apparatus comprising radio frequency power circuit providing enhanced plasma control

(75) Inventor: Jen-Yuan Yang, Taipei (TW)

Correspondence Address: TUNG & ASSOCIATES, 838 W. Long Lake Road, Suite 120, Bloomfield Hills, MI, 48302, US

(73) Assignee: Taiwan Semiconductor Manufacturing Co., Ltd.

(21) Appl. No.: 10/153,718

(22) Filed: May 22, 2002

(51) Int. Cl. C23C 16/00; H01L 21/306; C23F 1/00

(52) U.S. Cl. 156/345.44; 118/723 E; 118/723 R; 156/345.28; 156/345.43; 216/67; 427/569

(57) ABSTRACT

Within a plasma processing apparatus and a plasma processing method there is employed interposed between a decoupling capacitor and a radio frequency powered electrode a minimum of two adjustment capacitors. The minimum of two adjustment capacitors provide for enhanced plasma control within the plasma processing apparatus and the plasma processing method.

### BACKGROUND OF THE INVENTION

1. Field of the Invention

The present invention relates generally to plasma processing apparatus. More particularly, the present invention relates to plasma processing apparatus with enhanced plasma control.

2. Description of the Related Art

Common in the art of microelectronic fabrication for use when fabricating microelectronic fabrications are plasma processing apparatus. Plasma processing apparatus are common in the art of microelectronic fabrication insofar as plasma processing apparatus provide for efficient processing of microelectronic substrates, including both etch processing and deposition processing of microelectronic substrates, in large volumes.

While plasma processing apparatus are thus clearly desirable in the art of microelectronic fabrication and often essential in the art of microelectronic fabrication, plasma processing apparatus are nonetheless not entirely without problems in the art of microelectronic fabrication. In that regard, as microelectronic fabrication integration levels have increased and microelectronic fabrication device dimensions have decreased, it has become more difficult to adequately control plasma properties when operating plasma processing apparatus.

It is thus desirable in the art of microelectronic fabrication to provide plasma processing apparatus and plasma processing methods with enhanced plasma control.

It is towards the foregoing object that the present invention is directed.

Various aspects of plasma processing apparatus have been disclosed in the art of microelectronic fabrication.

Included among the disclosures, but not limited among the disclosures, are: (1) Gibson, Jr., in U.S. Pat. No. 6,110,395 (magnetic field aspects within plasma processing apparatus operation); (2) Lan et al., in U.S. Pat. No. 6,113,736 (component geometry aspects within plasma processing apparatus operation); and (3) Shan et al., in U.S. Pat. No. 6,232,236 (component electrical biasing aspects within plasma processing apparatus operation). In addition, although not necessarily specifically directed to plasma processing apparatus, Brand et al., in U.S. Pat. No. 6,101,102 discloses a fixed frequency regulation circuit for use within high frequency DC-DC power conversion applications.

Desirable in the art of microelectronic fabrication are additional plasma processing apparatus and plasma processing methods which provide enhanced plasma control.

It is towards the foregoing object that the present invention is directed.

### SUMMARY OF THE INVENTION

A first object of the present invention is to provide a plasma processing apparatus and a plasma processing method for plasma processing a microelectronic substrate.

A second object of the present invention is to provide a plasma processing apparatus and a plasma processing method in accord with the first object of the present invention, wherein the plasma processing apparatus and the plasma processing method provide enhanced plasma control.

In accord with the objects of the present invention, the present invention provides a plasma processing apparatus and a plasma processing method with enhanced plasma control.

In accord with the present invention, the plasma processing apparatus comprises a reactor chamber. The plasma processing apparatus also comprises a radio frequency powered electrode contained within the reactor chamber. The plasma processing apparatus also comprises a radio frequency power circuit powering the radio frequency powered electrode, wherein the radio frequency power circuit comprises: (1) a radio frequency power source separated from the radio frequency powered electrode by a decoupling capacitor; and (2) a minimum of two adjustment capacitors interposed between the decoupling capacitor and the radio frequency powered electrode, one terminal of each of the adjustment capacitors being electrically connected with the decoupling capacitor and the other terminal of each of the adjustment capacitors being connected to ground.

The present invention provides a plasma processing apparatus and a plasma processing method for plasma processing a microelectronic substrate, wherein the plasma processing apparatus and the plasma processing method provide enhanced plasma control.

The present invention realizes the foregoing object by employing within a radio frequency power circuit for powering a radio frequency powered electrode within a plasma apparatus a minimum of two adjustment capacitors interposed between a decoupling capacitor and the radio frequency powered electrode, where one terminal of each of the adjustment capacitors is electrically connected with the decoupling capacitor and the other terminal of each of the adjustment capacitors is connect to ground.

### BRIEF DESCRIPTION OF THE DRAWINGS

The objects, features and advantages of the present invention are understood within the context of the Description of the Preferred Embodiment, as set forth below. The Description of the Preferred Embodiment is understood within the context of the accompanying drawings, which form a material part of this disclosure, wherein:

FIG. 1 shows a schematic diagram of a plasma processing apparatus in accord with the present invention.

FIG. 2 shows a circuit diagram of a radio frequency power circuit within the plasma processing apparatus in accord with the present invention.

### DESCRIPTION OF THE PREFERRED EMBODIMENT

The present invention provides a plasma processing apparatus and a plasma processing method for plasma processing a microelectronic substrate, wherein the plasma processing apparatus and the plasma processing method provide enhanced plasma control.

The present invention realizes the foregoing object by employing within a radio frequency power circuit for powering a radio frequency powered electrode within a plasma processing apparatus a minimum of two adjustment capacitors interposed between a decoupling capacitor and the radio frequency powered electrode, where one terminal of each of the adjustment capacitors is electrically connected with the decoupling capacitor and the other terminal of each of the adjustment capacitors is connected to ground.

While the preferred embodiment of the present invention illustrates the present invention most particularly within the context of a gas ring laminated radio frequency powered platen electrode plasma processing apparatus which has particular application within plasma etch processing of microelectronic substrates, the present invention is not intended to be so limited. Rather the present invention may be employed for providing enhanced plasma control within plasma processing apparatus including but not limited to plasma etch apparatus and plasma deposition apparatus, providing the plasma processing apparatus have a radio frequency powered electrode, whether gas ring laminated or not.

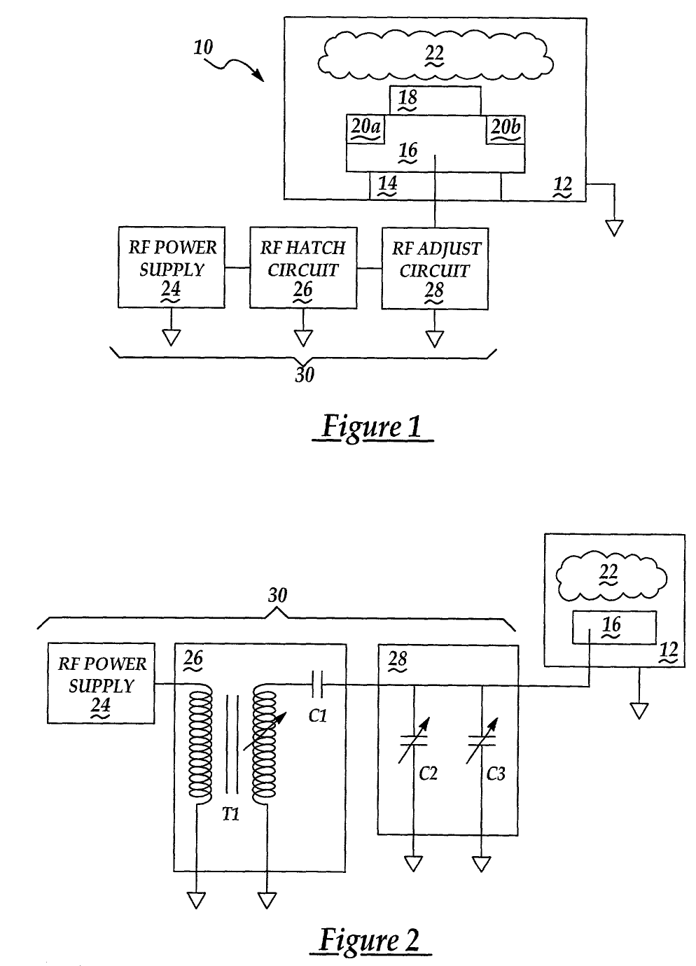

Referring now to FIG. 1, there is shown a schematic diagram illustrating a plasma processing apparatus in accord with the present invention.

As is illustrated within FIG. 1, a plasma processing apparatus 10 comprises a reactor chamber 12 suitable for operation at a reduced pressure which is generally required for sustaining a plasma 22 within the reactor chamber 12. There is also assembled within the reactor chamber 12 an insulator separator 14 upon which in turn is assembled a platen 16 (which may be, but is not limited to, a chuck). Positioned upon the platen 16 is a substrate 18 which is processed with the plasma 22. Also assembled peripherally surrounding a portion of the platen 16 is a pair of gas rings 20a and 20b which are intended as representative, in plan view, of a single annular gas ring which surrounds an upper periphery of the platen 16.

In order to form the plasma 22, the platen 16 is powered by a radio frequency power circuit 30 which comprises a radio frequency power supply 24 connected to a radio frequency matching circuit 16 in turn connected to a radio frequency power adjustment circuit 28 in turn connected to the platen 16, which serves as a radio frequency powered electrode. The reactor chamber 12 is in turn grounded such as to complete the radio frequency power circuit 30.

In accord with the present invention, further details of the radio frequency power circuit 30 are illustrated within the circuit diagram of FIG. 2.

FIG. 2 illustrates the radio frequency power supply 24 which supplies an input side of a variable transformer T1. An output side of the variable transformer T1 is connected to a first terminal of a first capacitor C1, which serves as a decoupling capacitor interposed between the radio frequency power supply 24 and the platen 16. Together, the variable transformer T1 and the first capacitor C1 comprise electrical components within the radio frequency matching circuit 26.

Interposed between the first capacitor C1 and the platen 16 a pair of capacitors designated as a second capacitor C2 and a third capacitor C3. The second capacitor C2 and the third capacitor C3 comprise components within the radio frequency power adjustment circuit 28. The second capacitor C2 and the third capacitor C3 serve as adjustment capacitors within the radio frequency adjustment circuit 28. As is illustrated within FIG. 2, one terminal of each of the second capacitor C2 and the third capacitor C3 is connected in common with an output terminal of the first capacitor C1. The other terminal of each of the second capacitor C2 and the third capacitor C3 is grounded.

Within the present invention, adjustment of the radio frequency plasma power through use of the second capacitor C2 and the third capacitor C3 allows for fine adjustment of plasma power within the plasma 22, thus providing for enhanced control of the plasma 22 when plasma processing the substrate 18 while employing the plasma 22.

Within the present invention, for plasma processing of a substrate 18, there is typically and preferably employed: (1) a radio frequency power supply 24; (2) a variable transformer T1; (3) a first capacitor C1 having a fixed capacitance; (4) a second capacitor C2 having a variable capacitance; and (5) a third capacitor C3 having a variable capacitance.

Within the context of the above limits for the electrical components within the radio frequency power circuit 30 as illustrated within the schematic diagram of FIG. 2, a plasma may be sufficiently controlled such as to provide a critical dimension bias control when etching a blanket microelectronic layer to form a patterned microelectronic layer (such as a patterned polysilicon containing gate electrode material layer) within about +/−0.002 microns. Such a favorable critical dimension control is particularly desirable within the context of the laminated gas ring plasma processing apparatus in accord with the present invention insofar as such a plasma processing apparatus generally has an enhanced susceptibility to drift in plasma properties since a gas ring is an integral part of a radio frequency powered electrode.

As is understood by a person skilled in the art, the preferred embodiment of the present invention is illustrative of the invention rather than limiting of the invention. Revisions and modifications may be made to components, structures and dimensions employed within a plasma processing apparatus in accord with the preferred embodiment of the present invention while providing a plasma processing apparatus and method thereof in accord with the present invention, further in accord with the appended claims.

What is claimed is:

1. A plasma processing apparatus comprising:
a reactor chamber;
a radio frequency powered electrode contained within the reactor chamber;
a radio frequency power circuit powering the radio frequency powered electrode, wherein the radio frequency power circuit comprises:
a radio frequency power source separated from the radio frequency powered electrode by a decoupling capacitor; and
a minimum of two adjustment capacitors interposed between the decoupling capacitor and the radio frequency powered electrode, one terminal of each of the adjustment capacitors being electrically connected with the decoupling capacitor and the other terminal of each of the adjustment capacitors being connected to ground.

2. The apparatus of claim 1 wherein the plasma processing apparatus is selected from the group consisting of plasma etching apparatus and plasma deposition apparatus.

3. The apparatus of claim 1 wherein the plasma processing apparatus is a plasma etching apparatus.

4. The apparatus of claim 3 wherein the plasma etching apparatus comprises a plasma reactant gas ring assembled to the radio frequency powered electrode.

5. The apparatus of claim 1 wherein;
the decoupling capacitor has a fixed capacitance;
a first of the adjustment capacitors has a variable capacitance; and
a second of the adjustment capacitors has a variable capacitance.

6. A plasma processing method comprising:
providing a plasma processing apparatus comprising:
a reactor chamber;
a radio frequency powered electrode contained within the reactor chamber;
a radio frequency power circuit powering the radio frequency powered electrode, wherein the radio frequency power circuit comprises:
a radio frequency power source separated from the radio frequency powered electrode by a decoupling capacitor; and
a minimum of two adjustment capacitors interposed between the decoupling capacitor and the radio frequency powered electrode, one terminal of each of the adjustment capacitors being electrically connected with the decoupling capacitor and the other terminal of each of the adjustment capacitors being connected to ground;
positioning a substrate upon the radio frequency powered electrode; and
plasma processing the substrate while adjusting the minimum of two adjustment capacitors.

7. The method of claim 6 wherein the plasma processing apparatus is selected from the group consisting of plasma etching apparatus and plasma deposition apparatus.

8. The method of claim 6 wherein the plasma processing apparatus is a plasma etching apparatus.

9. The method of claim 8 wherein the plasma etching apparatus comprises a plasma reactant gas ring assembled to the radio frequency powered electrode.

10. The method of claim 6 wherein;
the decoupling capacitor has a fixed capacitance;
a first of the adjustment capacitors has a variable capacitance; and
a second of the adjustment capacitors has a variable capacitance.
